(19) United States
(12) Patent Application Publication
(10) Pub. No.: US 2026/0260531 A1
(43) Pub. Date: Sep. 3, 2026

(54) SENSOR ELEMENT, TEST DEVICE, AND METHOD FOR TESTING A DATA CARRIER HAVING A SPIN RESONANCE FEATURE

(71) Applicant: GIESECKE+DEVRIENT CURRENCY TECHNOLOGY GMBH, Munchen (DE)

(72) Inventor: Stephan HUBER, Munchen (DE)

(21) Appl. No.: 18/862,758

(22) PCT Filed: May 5, 2023
(86) PCT No.: PCT/EP2023/025211

§ 371 Date: Nov. 4, 2024

(30) Foreign Application Priority Data
May 6, 2022 (DE) 10 2022 001 597.8

(51) Int. Cl. G07D 7/04

(52) U.S. Cl. CPC G07D 7/04

(57) ABSTRACT

A sensor element for testing a flat-surface data carrier having a spin resonance feature. The sensor element includes a magnetic core with an air gap, into which the flat-surface data carrier can be inserted for testing, a polarization device for generating a static magnetic flux in the air gap, and a resonator device for exciting the spin resonance feature of the data carrier to be tested in the air gap. The resonator device contains a plurality of stripline resonators, designed and configured to be operated independently at the same excitation frequency. The polarization device generates a homogeneous magnetic flux in the air gap so that the static magnetic flux for each pair of stripline resonators of the resonator device has substantially the same field strength at the position of a first stripline resonator as at the position of a second stripline resonator.

The invention relates to a sensor element for checking the authenticity of a flat-surface data carrier, in particular a banknote, having a spin resonance feature. The invention also relates to a test device having such a sensor element and to a method for testing authenticity using such a sensor element or such a test device.

Data carriers, such as value or identification documents, but also other valuable objects, such as brand-name articles, are often provided with security elements that allow the data carriers to be authenticated and that also serve as protection against unauthorized reproduction. It is well known in the field of machine authentication to use security elements with spin resonance features to secure documents and other data carriers. The security elements are provided with substances that have a spin resonance signature. The spin resonance signatures that can be used for authenticity testing include, in particular, nuclear magnetic resonance (NMR) effects, electron spin resonance (ESR) effects, and ferromagnetic resonance (FMR) effects.

In the process of checking banknotes, three different magnetic fields are usually generated in the measuring range of a banknote processing machine, for example, to detect the spin resonance signatures. This is specifically a quasi-static polarization field B₀, which runs parallel to the axial direction (z direction) of the air gap of a magnetic circuit. A second magnetic field is formed by a modulation field B_{mod}, which also runs parallel to the z-axis and typically has a frequency f_{mod} in the kHz range. For excitation of transitions between the split spin energy levels of the spin resonance signature substances, an excitation field B₁ is provided, which is polarized perpendicular to the B₀ direction. The excitation field oscillates at the resonance frequency of the material, which is also referred to as the Larmor frequency, and which is proportional to the polarization field B₀.

To generate the polarization field B₀, a magnetic circuit is often used that directs the magnetic flux of permanent magnets or coils to an air gap in which the testing of the flat-surface data carriers takes place.

A high-frequency resonator, for example a stripline resonator, is used for generating the excitation field B₁. This is a conductive structure with a characteristic length 1, which is arranged on a carrier. If the wavelength λ of the coupled-in high-frequency signal matches the dimension 1 of the conducting structure during the authenticity test, a standing wave can form in the resonator and the stripline resonator is in resonance at the excitation frequency associated with the wavelength λ. Since the extension of a stripline resonator in the plane of the carrier is significantly greater than perpendicular thereto, this is also referred to as the plane of the stripline resonator, which corresponds to the plane of the carrier.

With a sensor element having a stripline resonator, when a data carrier is tested via a scan a spatial resolution proportional to the dimension of the resonator can be achieved along the scan direction. Accordingly, a typical edge length of the stripline resonators of about 10 mm results in a spatial resolution in the range of several millimeters.

Based on this, the object of the invention is to provide an improved device for testing data carriers with spin resonance features, and in particular to provide a sensor element that also allows testing of data carriers having complex spin resonance features.

This object is achieved by the features of the independent claims. Developments of the invention are the subject of the dependent claims.

The invention provides a sensor element for testing, in particular testing the authenticity, of a flat-surface data carrier having a spin resonance feature. For example, the flat-surface data carrier can be a banknote. The sensor element contains a magnetic core with an air gap, into which the flat-surface data carrier can be inserted for testing, a polarization device for generating a static magnetic flux in the air gap, and a resonator device for exciting the spin resonance feature of the data carrier to be tested in the air gap. The spin resonance feature is preferably an ESR feature.

The resonator device contains a plurality of stripline resonators, which are preferably designed and configured for operation independently of one another at the same excitation frequency, for example with a frequency deviation of less than 1%, preferably of less than 0.1%. Furthermore, the polarization device generates a homogeneous magnetic flux in the air gap, so that the static magnetic flux for each pair of stripline resonators of the resonator device has substantially the same field strength at the position of a first stripline resonator as at the position of a second stripline resonator.

As described in more detail below, such a design of the resonator device and such a matching of the polarization device satisfies very extensive requirements on an automated testing of data carriers, in particular of banknotes. For example, the spatial resolution achieved can be used to check the completeness of the data carrier in the case of a spin resonance feature that is introduced into the data carrier in a flat shape. Even in the case of a localized spin resonance feature, a spatially resolved measurement of the feature can be carried out with the design according to the invention and thus a predetermined specified geometry and position of the feature can be checked.

In principle, the stripline resonators used are characterized in particular in that their sensitive region is very easily accessible and that they have a very high filling factor for flat-surface samples, such as those formed by the banknotes to be tested. The stripline resonators are sometimes referred to below as resonators purely for brevity.

In particular, in a sensor element according to the invention it is provided that the static magnetic flux at the location of each pair of stripline resonators of the resonator device has a maximum deviation of 2%.

In an advantageous configuration, the stripline resonators of the resonator device are arranged in the form of a one-dimensional array.

In particular, the resonator device can contain two, three, four, five or six stripline resonators, wherein a greater number of stripline resonators, for example a multitrack arrangement with two or three tracks with five stripline resonators each, can also be advantageous. While a one-dimensional array enables a spatially resolved measurement on a moving data carrier, a multitrack arrangement also allows a spatially resolved measurement to be made on a stationary data carrier.

Each of the stripline resonators of the resonator device is advantageously fed by a different signal source. Alternatively, the stripline resonators can also be powered by a single signal source via a multiplexer. A hybrid design is also possible, in which the stripline resonators of the resonator device are divided into multiple groups, and the resonators of each group are each fed by a single signal source via a multiplexer, while different groups are fed by different signal sources.

It is advantageous that the plurality of stripline resonators covers an area which captures the entire width of the data carrier to be tested, in particular a banknote. A linear scan along the length of the data carrier can then be used to check the data carrier for completeness, since each position on the data carrier is detected by a stripline resonator during the scan. If a test on a stationary test specimen is provided, the plurality of stripline resonators advantageously covers an area that captures the entire surface of the data carrier to be tested, in particular a banknote.

The stripline resonators of the resonator device advantageously have the same resonant frequency; for example, the resonant frequencies deviate from one another by less than 1%, preferably by less than 0.1%. The stripline resonators are preferably also designed and configured for testing the spin resonance feature in the same spatial mode of the excitation field, and particularly preferably, the stripline resonators have an identical geometric shape, for example, a square, a rectangular or an annular shape.

The air gap mentioned is advantageously bounded by two plane-parallel pole surfaces of the magnetic core. At the pole surfaces, the magnetic core is preferably made of a ferromagnetic material with a magnetic permeability μᵣ>>1, that is, in particular μᵣ greater than 1×10², but the pole surfaces can also be made of a paramagnetic material with μᵣ≈1, in particular, μᵣ is not more than 1+10⁻².

The stripline resonators are advantageously planar in design, with a main extension plane which is a plane parallel to at least one of the pole surfaces of the magnetic core bounding the air gap. The main extension plane is further advantageously perpendicular to the direction of the static magnetic flux generated by the polarization device. In this description, the direction of the static magnetic flux is also referred to as the z-direction. The main extension plane of the stripline resonators then extends in the x-y plane perpendicular to the z-direction.

In an advantageous embodiment, the sensor element further comprises a modulation device for generating a time-varying magnetic modulation field in the air gap, wherein the modulation frequency is preferably equal in all stripline resonators of the resonator device. For example, the modulation frequency at the location of any two stripline resonators differs by a maximum of 2% from each other. The modulation device is advantageously formed by a single modulation coil arranged in the air gap, in particular a single flat-surface coil.

The air gap advantageously has a height, i.e. a dimension in the z-direction, of less than 10 mm, preferably of less than 5 mm. This allows a particularly strong polarization field, i.e. a strong static magnetic flux, to be generated in the air gap.

The resonator device is advantageously arranged in the air gap such that a flat data carrier inserted for testing is located in the near field of the excitation field generated by the stripline resonators.

In an advantageous development of the invention, at least some of the said stripline resonators are each replaced by an N×M array of stripline resonators to increase the signal-to-noise ratio, where N and M are natural numbers and at least one of the values of N and M is greater than 1, wherein the stripline resonators of the N×M array are all fed from the same signal source and are electrically connected in parallel and/or in series.

In a particularly advantageous configuration, the sensor element furthermore comprises a ramp coil for creating a ramp function of the static magnetic flux.

The resonator device is advantageously designed for the excitation of spin resonance signals with a frequency above 1 GHz, in particular between 1 GHz and 10 GHz. Compared to lower frequencies, this allows a higher spectral resolution and a stronger measurement signal.

The resonator device is also designed in particular for detecting spin resonance signals of the spin resonance feature. The stripline resonators of the resonator device can in particular capture a response signal of the spin resonance feature and output it to a detector. The spin resonances can be determined, for example, with a continuous wave (CW) method, a pulsed method, or a rapid scan method.

The stripline resonators can be operated both in reflection and in transmission when testing the data carrier. The latter has the advantage that no element such as a circulator is required in the signal branch, which separates the signals leading from and returning to the resonator.

Advantageously, the resonator device comprises a flat-surface carrier on which the stripline resonators are applied. The carrier is conveniently formed by a printed circuit board, which allows for reproducible and cost-effective production. However, it is also advantageous, in particular to reduce dielectric losses in the carrier material, to use carriers based on ceramic, Teflon or hydrocarbons.

The invention also includes a test device for testing a flat-surface data carrier, in particular a banknote, having a spin resonance feature using a sensor element of the type described above. In addition, the test device comprises either a plurality of signal sources having the same excitation frequency, which are used to feed the stripline resonators of the resonator device, or comprises a single signal source from which the stripline resonators are fed via a multiplexer.

Advantageously, the test device also contains a transport device which introduces the flat-surface data carriers to be tested along a transport path into a test position in the air gap or passes them through a test position in the air gap of the magnetic core, wherein the resonator device is arranged in the air gap such that the test position is located in the near field of the excitation field generated by the stripline resonators.

The transport device is designed and configured in particular for high-speed transport, for example between 1 m/s and 12 m/s, of the flat-surface data carriers to be tested along the transport path.

The invention also includes a method for testing a flat-surface data carrier, in particular a banknote, having a spin resonance feature by means of a sensor element of the described type or a test device of the described type, wherein in the method
a flat-surface data carrier to be tested is inserted into the air gap of the magnetic core of the aforementioned sensor element,
a static magnetic flux is generated using the polarization device and a time-varying magnetic modulation field is generated in the air gap preferably using a modulation device, and
the resonator device is used to excite the spin resonance feature of the data carrier to be tested.

An advantage of the method is that the flat-surface data carrier to be tested is measured, in particular tested for completeness, in a spatially resolved manner by the excitation of the spin resonance feature.

In an advantageous conduct of the method, it is provided that the flat-surface data carrier to be tested is guided along a transport path through the air gap of the magnetic core of the said sensor element and in the process the stripline resonators of the resonator device are used to perform a single-track scan or a multi-track scan of the data carrier.

Further exemplary embodiments as well as advantages of the invention are explained below by reference to the figures, in the representation of which a true-to-scale and proportional reproduction has been omitted in order to increase the clarity.

### In the Drawing:

FIG. 1 schematically shows a test device of a banknote processing system for the measurement of spin resonances of a banknote test specimen,

FIG. 2 schematically shows a plan view of a resonator device of a sensor element according to the invention,

FIG. 3 schematically shows the setup in a measurement of a paper sample with the resonator device of FIG. 2,

FIG. 4 shows signal curves when measuring the spin resonance feature of the paper sample from FIG. 3, and

FIG. 5 shows a circuit for connecting the resonator device of a sensor element according to the invention with only one single signal branch.

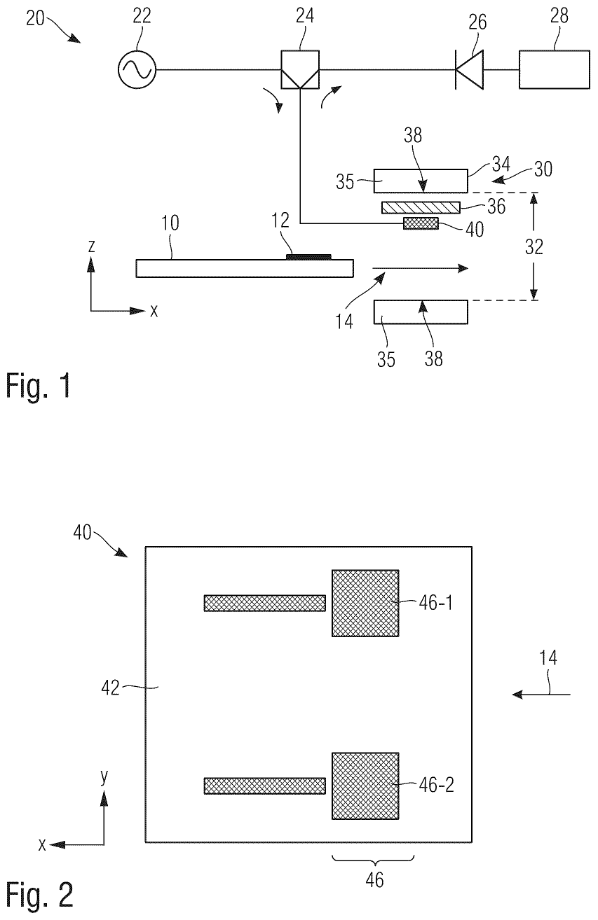

The invention is now explained using the example of testing the authenticity of banknotes. FIG. 1 schematically shows a test device 20 of a banknote processing system for the measurement of spin resonances of a banknote test specimen 10.

The banknote test specimen 10 contains a spin resonance feature 12, the characteristic properties of which are used to prove the authenticity of the banknote. The spin resonance feature may, as in the exemplary embodiment shown, only be present in a sub-region of the banknote or may also extend over the entire surface of the banknote test specimen.

The test device 20 contains a sensor element 30 with a magnetic core 35, which has an air gap 32 bounded by two pole surfaces 38, through which the banknote test specimen 10 is guided along a transport path 14 during the authenticity test.

For the detection of spin resonance signatures of the spin resonance feature 12, the sensor element 30 generates three different magnetic fields in a measuring range of the air gap 32.

Firstly, a homogeneous, static magnetic flux is generated parallel to the z-axis in the measuring range by a polarization device 34. In order to generate a strong polarization field, the height of the air gap in the z direction is advantageously less than 10 mm, in particular even less than 5 mm.

Secondly, a modulation device 36 generates a time-varying magnetic modulation field in the air gap, which also runs parallel to the z-axis and has a modulation frequency f_{Mod} in the range between 1 kHz to 1 MHz. Finally, a resonator device 40 generates an excitation field in the air gap, which induces the energy transitions between the spin energy levels in the spin resonance feature 12. The excitation field typically has frequencies above 1 GHz and is polarized perpendicular to the z direction.

The frequency of the excitation field is tuned to the Larmor frequency of the spin resonance feature 12 to be detected, in order to measure its spin resonance signature and to allow it to be used for the authenticity test. For this purpose, the test device 20 contains a signal source 22, the excitation frequency f_{MW} of which corresponds to the expected Larmor frequency of the spin resonance feature 12. The excitation signal from the signal source 22 is supplied via a duplexer 24 to a resonator device 40 and generates an alternating magnetic field of frequency f_{MW} there.

In addition to the said elements, the test device 20 includes a detector diode 26 for measuring the high-frequency power reflected by the resonator device 40 and an evaluation unit 28 for evaluating and optionally displaying the measurement result. If the spin resonance feature 12 is in resonance at a coupled-in frequency, the resonator quality changes, and with it the power reflected by the stripline resonators. Due to the modulation of the static polarization field by the modulation device 36, the exact value of the Larmor frequency of the sample oscillates so that the obtained measurement signal is amplitude-modulated with the modulation frequency.

FIG. 2 schematically shows the design of the resonator device 40 of a sensor element 30 according to the invention according to a first exemplary embodiment of the invention. The resonator device 40 comprises a flat-surface carrier, for example a printed circuit board 42, on which a plurality of stripline resonators 46 for a spatially resolved measurement are arranged, and which are operated independently of each other at the same excitation frequency.

Specifically, the resonator device 40 in the exemplary embodiment of FIG. 2 contains a 2×1 array of two stripline resonators 46-1, 46-2, which form a one-dimensional array extending perpendicular to the transport direction 14. As explained in more detail below, this means that the spin resonance intensity of the banknote test specimen 10 can be measured in a spatially resolved manner, namely along two tracks spaced apart parallel to the transport direction 14. FIG. 2 shows, purely to explain the functional principle, a small array with only 2×1 stripline resonators, but it is understood that in practice one-dimensional arrays with more than two, for example 3, 4, 5, 6 or 10, resonators are also possible in order to achieve a higher spatial resolution. Two-dimensional arrays, for example with 2×2, 2×4 or 2×10 resonators, are also possible and enable a spatially resolved measurement even on a stationary banknote test specimen 10. Preferably, the plurality of stripline resonators is arranged in the form of a linear array or in two dimensions at the grid points of a regular grid, for example in a rectangular, hexagonal or line-by-line arrangement.

The polarization device 34 generates a homogeneous static magnetic flux in the air gap 32, so that the static magnetic flux for each pair of stripline resonators 46-1, 46-2 of the resonator device 40 has substantially the same field strength at the position of a first stripline resonator 46-1 as at the position of a second stripline resonator 46-2. “Substantially” the same field strength means that the field strengths at the positions of the stripline resonators 46-1, 46-2 differ by a maximum of 2%.

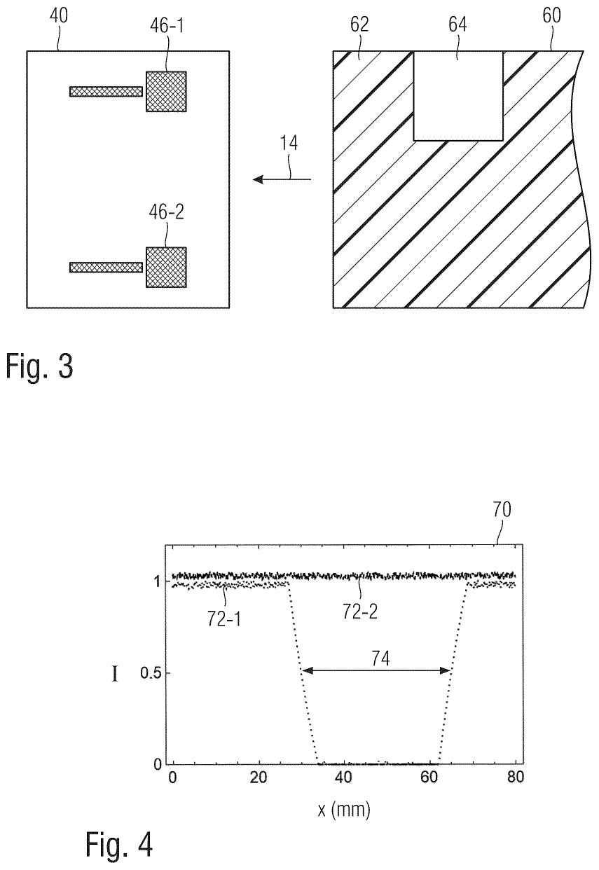

To demonstrate the operating principle of the invention, the behavior of a sensor element according to the invention having a resonator device 40 according to FIG. 2 was simulated in a setup according to FIG. 3.

The resonator device 40 contains two square V/2-stripline resonators 46-1, 46-2, which are constructed on a printed circuit board 42 with a thickness of 1.5 mm and with a dielectric constant of 3.66. The resonators 46-1, 46-2 have an edge length of 7.1 mm, corresponding to a resonance frequency of 9.8 GHz, and are arranged on the printed circuit board 42 in the y-direction perpendicular to the transport direction 14 at a distance of 50 mm apart.

To connect to the signal source 22 via a circulator, the impedance of the resonators 46-1, 46-2 is transformed to 50Ω using a λ/4 transformer. The polarization field B₀ and the modulation field B_{mod} are identical at the location of the two resonators 46-1, 46-2.

With reference to FIG. 3, a measurement on a suitably prepared paper sample 60 was simulated using such a resonator device 40. For this purpose, a paper sample with a height of 100 mm was first loaded with a spin resonance feature 62 over its entire surface. After the feature loading, a 35 mm×35 mm portion was cut out from the top of the sample and replaced by a feature-free paper portion 64.

As shown in FIG. 3, the sample 60 prepared in this way is moved along the transport direction 14 centrally over the resonator device 40 with the two stripline resonators 46-1, 46-2, and the resulting spin resonance signal is recorded. At the given polarization field strength, the Larmor frequency of the spin resonance feature corresponds exactly to the resonance frequency of 9.8 GHz of the two resonators 46-1, 46-2.

In diagram 70 of FIG. 4, the simulated signal intensities thus obtained are shown as a function of the position x for the upper resonator 46-1 as signal curve 72-1 and for the lower resonator 46-2 as signal curve 72-2.

The signal curves were normalized to the mean signal intensity of the undisturbed signal curve 72-2 and displayed slightly offset for better clarity.

In FIG. 4 it can be clearly seen that from the signal dropout 74 of the upper resonator 46-1, the feature-free region 64 of the sample 60 can be detected easily. With a single resonator, over which the paper sample 60 moves, for example, centrally, this would not be possible.

In this exemplary embodiment, the ordinate is labeled as I and indicates the normalized intensity. The abscissa is labeled as x and indicates the position in mm.

The plurality of stripline resonators of the resonator device can be advantageously operated by means of independent signal sources. However, this also requires that the stripline resonators are connected to independent signal branches, which requires, in particular with a large number of resonators, a large installation space for the circuit implementation.

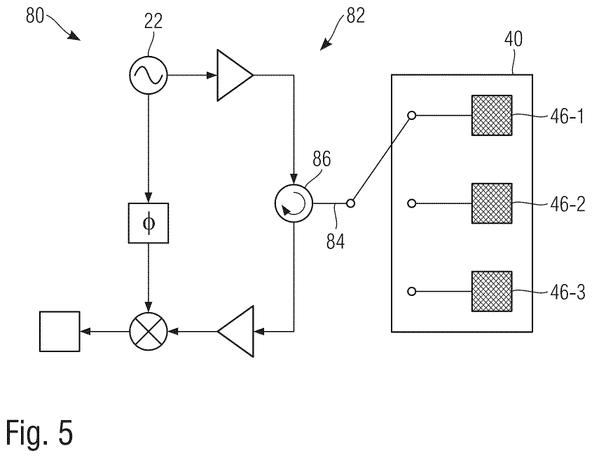

FIG. 5 shows an alternative circuit 80 for connecting a resonator device 40 of a sensor element according to the invention to only one single signal branch 82. All three stripline resonators 46-1, 46-2, 46-3 of the resonator device 40 are connected via a multiplexer 84 to the circulator 86 of this signal branch. Since only one signal branch 82 with only one signal source 22 is used, the required installation space is small. It is also ensured without additional measures that the stripline resonators 46-1, 46-2, 46-3 are operated with the same excitation frequency. For the sake of simplicity, the circuit 80 of FIG. 5 is shown with three resonators, but using a multiplexer, a different, in particular larger, number of resonators can also be fed from a single signal source 22.

When a circuit 80 according to FIG. 5 is used, however, only a single resonator 46-1, 46-2 or 46-3 can be used for measurement at any one time. Thus, gaps are created in the transport direction between the locations on the test specimen at which the spin resonance is measured, and hence there are locations at which no measurement takes place. Measuring points in adjacent tracks are offset relative to each other in the transport direction.

Depending on the requirements of an application in terms of the required installation space and the spatial resolution of the measurement, a hybrid solution can also be selected, in which the stripline resonators of the resonator device are divided into multiple groups, the resonators of which are each connected to a single signal branch. For example, a resonator device having 9 stripline resonators can be divided into three groups with three resonators each, which are each connected to a single signal branch via a multiplexer. In this way, the required installation space can be reduced to approximately one third while at the same time a high measurement coverage of the test specimen can be obtained.

List of reference signs

| | |
|---|---|
| 10 | banknote test specimen |
| 12 | spin resonance feature |
| 14 | transport path |
| 20 | test device |
| 22 | signal source |
| 24 | duplexer |
| 26 | detector diode |
| 28 | evaluation unit |
| 30 | sensor element |
| 32 | air gap |
| 34 | polarization device |
| 35 | magnetic core |
| 36 | modulation device |
| 38 | pole surfaces |
| 40 | resonator device |
| 42 | carrier |
| 46-1, 46-2, 46-3 | stripline resonators |
| 60 | paper sample |
| 62 | spin resonance feature |
| 64 | feature-free paper portion |
| 70 | diagram |
| 72-1, 72-2 | signal curves |
| 74 | signal dropout |
| 80 | circuit |
| 82 | signal branch |
| 84 | multiplexer |
| 86 | circulator |

1.-19. (canceled)

20. A sensor element for checking a flat-surface data carrier, having a spin resonance feature, with
a magnetic core with an air gap into which the flat-surface data carrier can be inserted for testing,
a polarization device for generating a static magnetic flux in the air gap, and
a resonator device for exciting the spin resonance feature of the data carrier to be tested in the air gap,
wherein the resonator device contains a plurality of stripline resonators, which are designed and configured to be operated independently of one another at the same excitation frequency, and
the polarization device generates a homogeneous magnetic flux in the air gap, so that the static magnetic flux for each pair of stripline resonators of the resonator device has substantially the same field strength at the position of a first stripline resonator as at the position of a second stripline resonator.

21. The sensor element according to claim 20, wherein the static magnetic flux at the location of each pair of stripline resonators of the resonator device has a maximum deviation of 2%.

22. The sensor element according to claim 20, wherein the stripline resonators of the resonator device are arranged in the form of a one-dimensional array.

23. The sensor element according to claim 20, wherein each of the stripline resonators of the resonator device is fed by a different signal source.

24. The sensor element according to claim 20, wherein the plurality of stripline resonators covers an area that captures the entire width of the data carrier to be tested.

25. The sensor element according to claim 20, wherein the stripline resonators of the resonator device have the same resonant frequency, in that the stripline resonators moreover are designed and configured to test the spin resonance feature in the same spatial mode of the excitation field, in that the stripline resonators have an identical geometric shape.

26. The sensor element according to claim 20, wherein the air gap is bounded by two plane-parallel pole surfaces of the magnetic core.

27. The sensor element according to claim 20, wherein the stripline resonators are designed with a flat surface having a main extension plane which is plane-parallel to at least one of the pole surfaces of the magnetic core bounding the air gap.

28. The sensor element according to claim 20, wherein the sensor element has a modulation device for generating a time-varying magnetic modulation field in the air gap,
wherein the modulation frequency for all of the stripline resonators of the resonator device is equal.

29. The sensor element according to claim 28, wherein the modulation device is formed by a single modulation coil arranged in the air gap.

30. The sensor element according to claim 20, wherein the stripline resonators are designed with a flat surface having a main extension plane which is perpendicular to the direction of the static magnetic flux generated by the polarization device.

31. The sensor element according to claim 20, wherein the air gap has a height of less than 10 mm.

32. The sensor element according to claim 20, wherein the resonator device is arranged in the air gap in such a way that a flat-surface data carrier inserted for testing is located in the near field of the excitation field generated by the stripline resonators.

33. A test device for testing a flat-surface data carrier having a spin resonance feature, with
a sensor element according to claim 20, and
either a plurality of signal sources having different excitation frequencies, from which the stripline resonators of the resonator device are fed,
or a single signal source from which the stripline resonators are fed via a multiplexer.

34. The test device according to claim 33, having a transport device which introduces the flat-surface data carriers to be tested along a transport path into a test position in the air gap or passes them through a test position in the air gap of the magnetic core, wherein the resonator device is arranged in the air gap such that the test position is located in the near field of the excitation field generated by the stripline resonators.

35. The test device according to claim 34, wherein the transport device is designed and configured for high-speed transport of the flat-surface data carriers to be tested along the transport path.

36. A method for testing a flat-surface data carrier, having a spin resonance feature, by means of a sensor element or a test device according to claim 33,
wherein in the method
a flat-surface data carrier to be tested is inserted into the air gap of the magnetic core of the aforementioned sensor element,
a static magnetic flux is generated using the polarization device and a time-varying magnetic modulation field is generated in the air gap using a modulation device, and
the resonator device is used to excite the spin resonance feature of the data carrier to be tested.

37. The method according to claim 36, wherein the flat-surface data carrier to be tested is measured in a spatially resolved manner, tested for completeness, by the excitation of the spin resonance feature.

38. The method according to claim 36, wherein the flat-surface data carrier to be tested is guided along a transport path through the air gap of the magnetic core of the said sensor element and in the process the stripline resonators of the resonator device are used to perform a single-track scan or a multi-track scan of the data carrier.
